(19) United States
(12) Patent Application Publication
(10) Pub. No.: US 2024/0305056 A1
(43) Pub. Date: Sep. 12, 2024

(54) LASER LIGHT SOURCE SYSTEM

(71) Applicant: AUO Corporation, Hsin-Chu (TW)

(72) Inventors: YU-SHENG LIN, Hsin-Chu (TW); Shun-Ping Chiao, Hsin-Chu (TW); Yu-Chin Wu, Hsin-Chu (TW); Cheng-Han Chung, Hsin-Chu (TW); Yao-An Mo, Hsin-Chu (TW); Han-Chung Lai, Hsin-Chu (TW)

(21) Appl. No.: 18/396,843

(22) Filed: Dec. 27, 2023

(30) Foreign Application Priority Data
Mar. 9, 2023 (TW) 112108685

(51) Int. Cl. H01S 3/00; G02B 5/18; G02B 27/30

(52) U.S. Cl. CPC H01S 3/005; G02B 5/1866; G02B 27/30

(57) ABSTRACT

A laser light source system is used to simultaneously irradiate a plurality of pads on a display substrate and a plurality of light emitting components. The laser light source system includes a laser light source, a collimator lens, a diffractive optical component and a refractive component. The laser light source is configured to provide a laser beam. The collimator lens is disposed on a path of the laser beam to generate a collimated beam. The diffractive optical component is disposed on a path of the collimated beam to generate a plurality of sub beams. The display substrate is disposed on a focal plane of the refractive component, so as to utilize the sub beams to bond the light emitting components to the pads.

### CROSS-REFERENCE TO RELATED PATENT APPLICATION

This non-provisional application claims priority to and the benefit of, pursuant to U.S.C. § 119(a), patent application Ser. No. 11/210,8685 filed in Taiwan on Mar. 9, 2023. The disclosure of the above application is incorporated herein in its entirety by reference.

Some references, which may include patents, patent applications and various publications, are cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference were individually incorporated by reference.

### FIELD

The present disclosure relates to a laser light source system.

### BACKGROUND

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

In the manufacturing process of display panels, it is necessary to use a laser to bond conductive components, or to bond the conductive components to a conductive metal layer. However, the size of the laser spot is often much larger than the size of the bonding area, such that heat diffuses to other areas, thus affecting the yield. As shown in FIG. 1, in a comparative embodiment of manufacturing a display device 10, the laser spot SP is used to irradiate the light emitting components LD and corresponding metal pads PA on the substrate, thus bonding the light emitting components LD to the pads PA. In this comparative embodiment, the size of the laser spot SP is much larger than the sizes of the light emitting components LD and the pads to be bonded, thus causing heat diffusion of the laser light to regions that do not require irradiation.

To prevent the issue of the heat diffusion, in certain related arts, a mask having array-type transparent holes is disposed on the laser optical path to block the regions outside the pads PA. However, such approach may reduce the utilization rate of the laser light.

### SUMMARY

The present disclosure provides a laser light source system, which is used to simultaneously irradiate a plurality of pads on a display substrate and a plurality of light emitting components. No mask is disposed on the laser optical path, which does not reduce the utilization rate of the laser light, and a ratio of the laser light irradiating the regions outside the pads is low.

According to one embodiment of the present disclosure, a laser light source system is provided, which is used to simultaneously irradiate a plurality of pads on a display substrate and a plurality of light emitting components. The laser light source system includes a laser light source, a collimator lens, a diffractive optical component and a refractive component. The laser light source is configured to provide a laser beam. The collimator lens is disposed on a path of the laser beam to generate a collimated beam. The diffractive optical component is disposed on a path of the collimated beam to generate a plurality of sub beams. The display substrate is disposed on a focal plane of the refractive component, so as to utilize the sub beams to simultaneously irradiate the pads on the display substrate and the light emitting components to bond the light emitting components to the pads.

Based on the foregoing, the laser light source system according to the embodiment of the present disclosure utilizes the diffractive optical component to split the laser beam. A quantity of the laser sub beams after splitting is plural, allowing simultaneous bonding processes between the pads and the light emitting components to be performed. Further, the laser sub beams after splitting are only directed to the pads and the light emitting components to be bonded, which may reduces the area of the regions that do not require irradiation on the substrate to be irradiated by the laser light, thus reducing a waste of the laser light energy.

These and other aspects of the present disclosure will become apparent from the following description of the embodiment taken in conjunction with the following drawings, although variations and modifications therein may be effected without departing from the spirit and scope of the novel concepts of the disclosure.

The detailed features and advantages of the present disclosure are described below in great detail through the following embodiment with reference to the accompanying drawings as follows.

### BRIEF DESCRIPTION OF THE DRAWINGS

The accompanying drawings illustrate one or more embodiments of the disclosure and together with the written description, serve to explain the principles of the disclosure. Wherever possible, the same reference numbers are used throughout the drawings to refer to the same or like elements of an embodiment, and wherein:

FIG. 1 is a schematic view of a manufacturing method of a display device according to a comparative embodiment.

FIG. 2A is a schematic view of a laser light source system according to an embodiment of the present disclosure.

FIG. 2B is a schematic view of a manufacturing method of a display device according to an embodiment of the present disclosure.

FIG. 2C is a schematic view of pixels according to an embodiment of the present disclosure.

FIG. 3 is a schematic view of a laser light source system according to an embodiment of the present disclosure.

FIG. 4A is a schematic view of pixels according to an embodiment of the present disclosure.

FIG. 4B is a schematic view of a mask according to an embodiment of the present disclosure.

### DETAILED DESCRIPTION

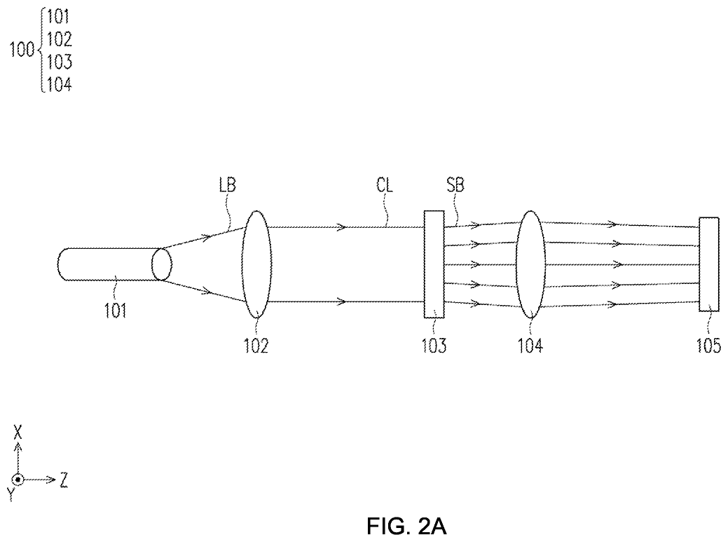

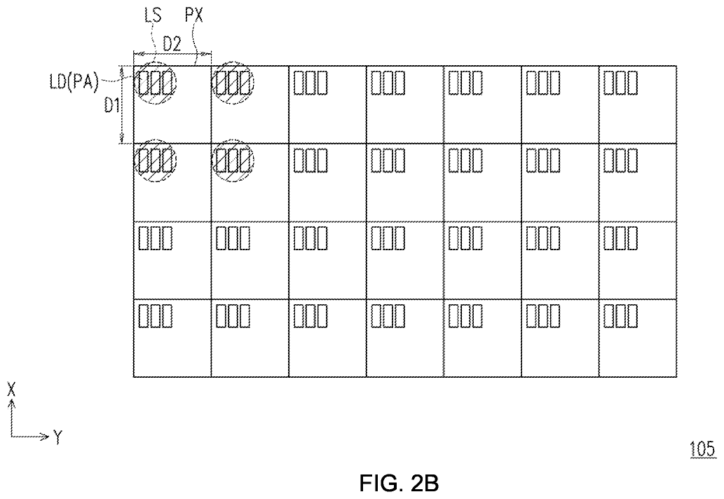

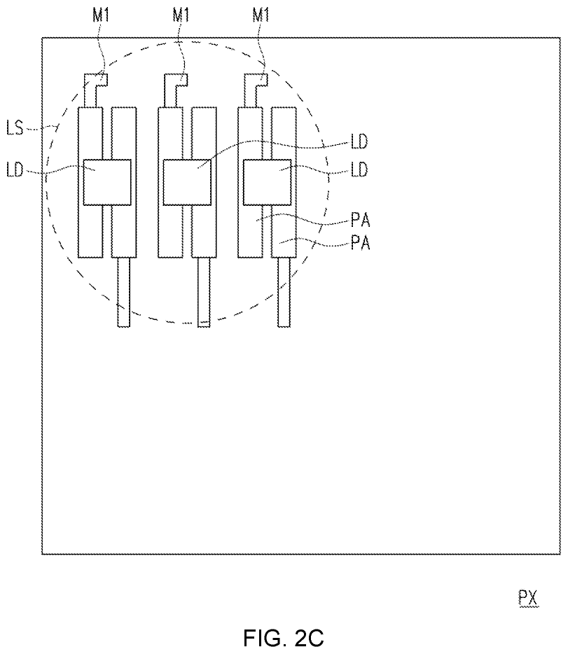

Referring to FIG. 2A, FIG. 2B and FIG. 2C, a laser light source system 100 includes a laser light source 101, a collimator lens 102, a diffractive optical component 103 and a refractive component 104. The laser light source 101 is configured to provide a laser beam LB. The collimator lens 102 is disposed on a path of the laser beam LB to generate a collimated beam CL. The diffractive optical component 103 is disposed on a path of the collimated beam CL to generate a plurality of sub beams SB. The refractive component 104 may be implemented by one or more lenses.

The laser light source system 100 is used to irradiate a display substrate 105. The display substrate 105 has a plurality of pixels PX, and each of the pixels PX may include one or more pads PA. Specifically, the display substrate 105 is disposed on a focal plane of the refractive component 104, so as to utilize the sub beams SB to simultaneously irradiate the pads PA on the display substrate 105 and the light emitting components LD to bond the light emitting components LD to the pads PA. In certain embodiments, the light emitting components LD may be light emitting diodes (LEDs).

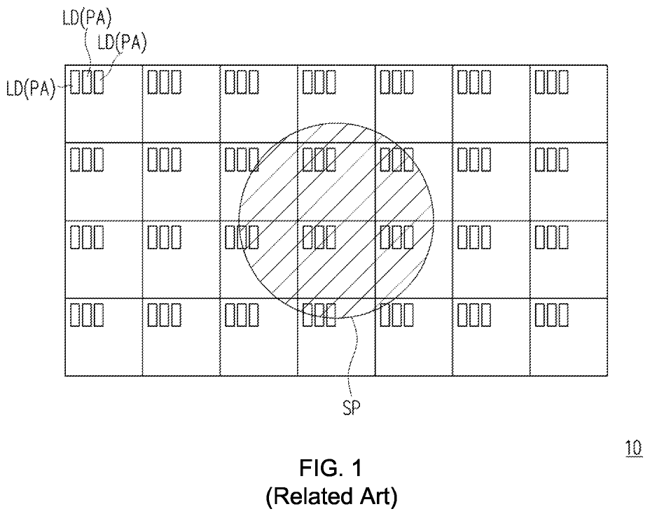

Specifically, the embodiment of the present disclosure utilizes the diffractive optical component 103 to split the collimated beam, and the laser sub beams SB generated after splitting are directed to the pads PA and the light emitting components LD to be bonded, thus softening the pads PA to be bonded to the light emitting components LD. Compared to the laser spots SP in FIG. 1, which significantly irradiate the regions other than the pads PA and the light emitting components LD, the laser light source system 100 provided by the present embodiment may reduce the area of the regions that do not require irradiation to be irradiated, thus reducing the waste of the energy of the laser beam LB. In addition, a quantity of the laser sub beams SB after splitting is plural, allowing simultaneous bonding processes between the pads PA and the light emitting components LD to be performed, which may be used in main bonding technology.

In one embodiment of the present disclosure, when the process of bonding the light emitting components LD to the pads PA is carried out using the laser light source system 100, compared to the case without using the diffractive optical element 103, the processing time is reduced from 26.8 s to 6.95 s, thus resulting in an increase of 2.8 times in productivity.

In addition, compared to the related art where the array-type transparent holes on the laser optical path are utilized to block the regions that do not require irradiation, the laser light source system 100 provided by the present embodiment utilizes the diffraction effect to determine the spatial distribution of light, without the need to dispose the array-type transparent holes on the optical path of the laser beam LB, and thus does not compromise the utilization rate of the laser beam LB.

In certain embodiments, the diffractive optical component 103 is designed according to a pitch of the pixels PX of the display substrate 105. Using the embodiment as shown in FIG. 2B as an example, the sub beams SB form a plurality of light spots LS discrete from each other in the form of a two-dimensional array on the display substrate 105. In the X-direction, an interval between adjacent light spots LS is identical to a width D1 of each pixel PX in the X-direction (a spatial period D1 of the pixels PX in the X-direction). In the Y-direction, an interval between adjacent light spots LS is identical to a width D2 of each pixel PX in the Y-direction (a spatial period D2 of the pixels PX in the Y-direction). However, the present disclosure is not limited thereto. In a selected direction, the interval between adjacent light spots LS and the spatial period of the pixels PX may be in a multiple relationship. In certain embodiments, the interval between the adjacent light spots LS in the X-direction may be different from the interval between the adjacent light spots LS in the Y-direction.

For ease of understanding, the two-dimensional array of the light spots LS is in a 2×2 form in the X-direction and the Y-direction perpendicular to each other, but the present disclosure is not limited thereto. In certain embodiments, the X-direction is not parallel to or perpendicular to the Y-direction. In certain embodiments, the light spots LS are distributed in an N×M form, where N and M are any positive integers, and N may be equal to or not equal to M.

In the embodiment of the present disclosure, the light spots LS completely cover each corresponding one of the pads PA to soften the pads PA, and a ratio of a total area of one or more pads PA being covered to an area of a corresponding light spot LS is 0.5% to 9%. Using the embodiment as shown in FIG. 2C as an example, the light spot LS completely covers six pads PA.

In certain embodiments, a width of the light spot LS may be 15 μm to 450 μm, and a power density thereof may be 4 W/mm² to 20 W/mm². When the pads PA include Ti, Sn or Ni, the wavelength of the laser beam LB may be 900 nm˜1064 nm to increase the optical absorptivity. When the pads PA include Ti, Cu, Sn or Ni, the wavelength of the laser beam LB may be 350 nm˜532 nm to increase the optical absorptivity.

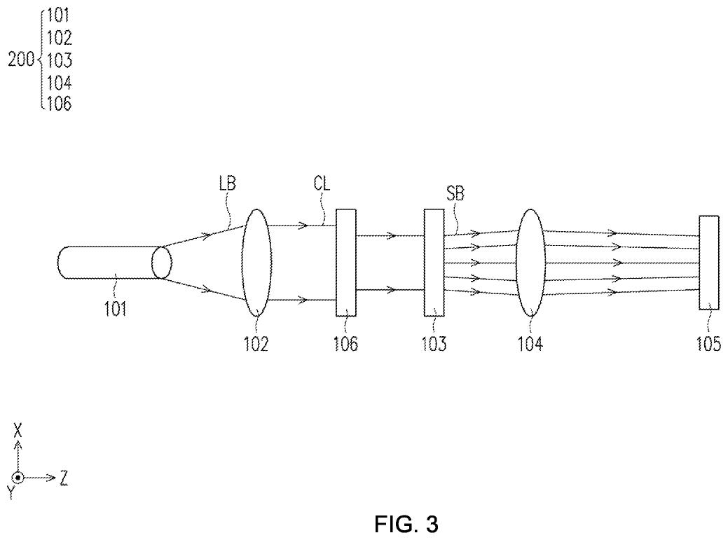

Referring to FIG. 3, a laser light source system 200 according to another embodiment of the present disclosure is provided, which is different from the laser light source system 100 in that a mask 106 is disposed between the collimator lens 102 and the diffractive optical component 103. The mask 106 has a patterned slit, and a shape of the patterned slit corresponds to a pad configuration pattern of the display substrate 105.

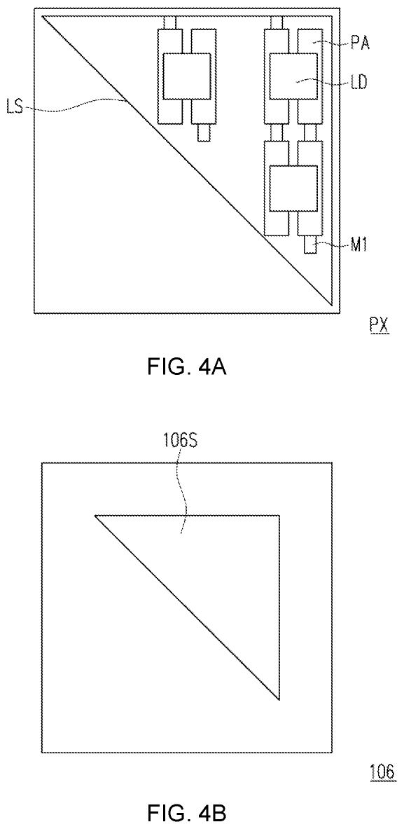

Specifically, referring simultaneously to FIG. 3, FIG. 4A and FIG. 4B, in one embodiment, a single pixel PX of the display substrate 105 has six pads PA as shown in FIG. 4A, which are used to bond three light emitting components LD. The three light emitting components LD may be, for example, a red micro LED, a green micro LED and a blue micro LED. The six pads PA are arranged in a triangle (the pad configuration pattern). The mask 106 is configured to have a triangular slit 106S. In this case, when the collimated beam CL passes the mask 106, the light spot shape thereof is formed as a triangle, and thus, after further passing and splitting by the diffractive optical component 103, a plurality of triangular light spots LS are formed on the display substrate 105, and each of the triangular light spots LS covers the corresponding six pads PA as shown in FIG. 4A.

In the present embodiment, by forming the shape of the slit 106S to correspond to the pad configuration pattern as a triangle, the shape of each light spot LS may be formed as a triangle, thus further reducing the proportion of the laser beam LB irradiating the regions outside the one or more pads PA, and avoiding heat diffusion. In other embodiments, the shape of the slit 106S that corresponds to the pad configuration pattern may be, for example, a circle or a rectangle, and is not limited to the triangle.

In sum, the laser light source system according to the embodiment of the present disclosure utilizes the diffractive optical component to split the laser beam. A quantity of the laser sub beams after splitting is plural, allowing simultaneous bonding processes between the pads and the light emitting components to be performed. Further, the laser sub beams after splitting are only directed to the pads and the light emitting components to be bonded, which may reduces the area of the regions that do not require irradiation on the substrate to be irradiated by the laser light, thus reducing a waste of the laser light energy, thereby reducing the processing time without increasing the laser light power, and enhancing the productivity.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to activate others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A laser light source system, configured to simultaneously irradiate a plurality of pads on a display substrate and a plurality of light emitting components, the laser light source system comprising:
a laser light source, configured to provide a laser beam;
a collimator lens, disposed on a path of the laser beam to generate a collimated beam;
a diffractive optical component, disposed on a path of the collimated beam to generate a plurality of sub beams; and
a refractive component, wherein the display substrate is disposed on a focal plane of the refractive component, so as to utilize the sub beams to simultaneously irradiate the pads on the display substrate and the light emitting components to bond the light emitting components to the pads.

2. The laser light source system according to claim 1, wherein the display substrate has a plurality of pixels, each of the pixels comprises at least one of the pads, and the diffractive optical component is designed according to a pitch of the pixels.

3. The laser light source system according to claim 2, wherein the sub beams form a plurality of light spots discrete from each other, and the light spots completely cover the corresponding pads.

4. The laser light source system according to claim 2, further comprising a mask, disposed between the collimator lens and the diffractive optical component, wherein the mask has a patterned slit, and a shape of the patterned slit corresponds to a pad configuration pattern of the display substrate.

5. The laser light source system according to claim 4, wherein the shape of the patterned slit is one of a rectangle, a circle or a triangle.

6. The laser light source system according to claim 3, wherein a ratio of a total area of the pads being covered to an area of a corresponding one of the light spots is 0.5% to 9%.

7. The laser light source system according to claim 3, wherein the light spots irradiate the pads on the display substrate and the light emitting components in a form of a two-dimensional array.

8. The laser light source system according to claim 7, wherein quantities of the light spots differ in two non-parallel directions.

9. The laser light source system according to claim 7, wherein intervals of the light spots differ in two non-parallel directions.
